(19) United States
(12) Patent Application Publication
(10) Pub. No.: US 2024/0030094 A1
(43) Pub. Date: Jan. 25, 2024

(54) HEAT DISSIPATION DEVICE FOR A CONVERTER FOR A VEHICLE, POWER CONVERTER, ELECTRIC AXLE DRIVE, VEHICLE AND METHOD FOR PRODUCING A HEAT DISSIPATION DEVICE

(71) Applicant: ZF Friedrichshafen AG, Friedrichshafen (DE)

(72) Inventors: Thomas Bosch, Horgenzell (DE); Manuel Raimann, Salem (DE)

(73) Assignee: ZF Friedrichshafen AG, Friedrichshafen (DE)

(21) Appl. No.: 18/355,245

(22) Filed: Jul. 19, 2023

(30) Foreign Application Priority Data
Jul. 21, 2022 (DE) 102022207429.7

(51) Int. Cl. H01L 23/373; H01L 23/367; H05K 7/20

(52) U.S. Cl. CPC H01L 23/3737; H01L 23/3677; H05K 7/209

(57) ABSTRACT

A cooling device for a power converter for a vehicle includes a heat sink having a heat discharging structure on a first side for discharging heat acting on the heat sink, and a connecting surface on the second side opposite the first side for absorbing heat from a semiconductor connected to the connecting surface, wherein the semiconductor has a discharge surface for discharging heat to the connecting surface, and an insulating layer having a polymer with ceramic particles that is located between the connecting surface on the heat sink and the discharge surface on the semiconductor, and is designed to mechanically and thermally connect the heat sink to the semiconductor and to insulate them from one another.

### CROSS-REFERENCE TO RELATED APPLICATION

This application claims priority to German Application No. DE 10 2022 207 429.7, filed on July 21, 2022, the entirety of which is hereby fully incorporated by reference herein.

### FIELD

The present invention relates to a cooling device for a power converter for a vehicle, a power converter, an electric axle drive, a vehicle and a method for producing a cooling device.

### BACKGROUND AND SUMMARY

Power converters are used in many fields, including the automotive industry.

DE 10 2015 211 202 A1 describes a converter housing that is installed in a vehicle and has a plate-shaped body.

Based on this, the present invention results in an improved cooling device for a power converter for a vehicle, an improved power converter, an improved axle drive, an improved vehicle, and an improved method for producing a cooling device according to the present disclosure. Advantageous embodiments can be also derived from the following description.

The following approach results in a means for obtaining a connection that is materially bonded and insulated. Obtaining both of these functions with the connection saves time during the production of the cooling device as well as reducing production costs.

A cooling device for a power converter for a vehicle is proposed. The cooling device has a heat sink that has a heat discharging structure on one side for discharging heat acting on the heat sink, and a connecting surface on the other side for absorbing heat from a semiconductor attached to the connecting surface. The cooling device also has a semiconductor that has a discharge surface for discharging heat to the connecting surface, and an insulating layer that contains a polymer with ceramic particles, which is placed between the connecting surface on the heat sink and the discharge surface of the semiconductor. The insulating layer is designed to mechanically and thermally connect the heat sink and the semiconductor to one another while insulating them electrically from one another.

The heat discharging structure on the heat sink can contain numerous fins, for example, through which heat can be released into the environment surrounding the heat sink. The heat can be absorbed through the connecting surface. The semiconductor can be formed by or on a circuit board with which the power converter is controlled. The insulating layer can be an insulating medium. The selection of the insulating material can result in cost reductions in comparison with a conventional production process, and eliminate the need for a soldering or sintering process. The approach proposed herein can advantageously eliminate the need for a permanent pressure to be applied in order to connect the semiconductor to the heat sink.

According to one embodiment, the insulating layer can be connected in a material bonded manner to the connecting surface and the discharge surface, e.g. with an adhesive. More precisely, the insulating layer can form an adhesive that functions like a glue. This has the advantage of forming a reliable and durable connection between the semiconductor and the heat sink.

The insulating layer can also be embedded in the polymer or it can contain ceramic particles applied to the polymer. This means that the individual materials can be layered or blended together. The insulating layer can advantageously be placed on the connecting surface on the heat sink and/or on the heat discharge surface on the semiconductor. This embodiment has the advantage of having an effective electrical insulation as a result of the use of ceramic particles.

The semiconductor can also be a potted (e.g. uninsulated) electronic component. This approach reduces costs because the semiconductor does not need to be insulated.

According to one embodiment, the cooling device can have at least one more semiconductor, which has another heat discharge surface with which this second semiconductor can be attached to the connecting surface. There can also be another insulating layer containing a polymer with ceramic particles that can be placed between the connecting surface and the second heat discharge surface on the second semiconductor with which the heat sink and the second semiconductor can be mechanically and thermally connected to one another and electrically insulated from one another. The second semiconductor can also be an uninsulated potted electronic component. By way of example, the semiconductors can be adjacent to one another on the connecting surface. The insulating layer can also cover the entire connecting surface. It is also conceivable for there to be another insulating layer between the connecting layer and the second heat discharge surface. This embodiment has the advantage of a more effective cooling while occupying less space.

The heat sink can also contain a metal, in particular copper or aluminum. The heat can be removed more effectively by an appropriate selection of the material for the heat sink, because metals generally exhibit good heat conductivity. Copper is also a good electrical conductor.

The invention also relates to a power converter, in particular an inverter, for a motor vehicle with a cooling device. The power converter is distinguished by the cooling device described herein.

The advantages of the approach presented herein can also be obtained quickly and efficiently with this embodiment.

The power converter can contain a housing in one embodiment, in which the cooling device is thermally and/or mechanically coupled to the housing. The connecting surface on the heat sink can also be flush with an outer wall of the housing. The housing can contain a plastic and be designed to protect the power converter from external effects, e.g. moisture or contaminants. The connecting surface and the outer wall can be flush to one another within a tolerance range. This means that a small gap can exist between the outer wall and the connecting surface (e.g. of up to 2 mm), which compensates for thermal expansion and thus protects the power converter against malfunctioning.

The invention also relates to an electric axle drive for a motor vehicle that has at least one electric machine, one transmission, and one power converter. The electric axle drive is distinguished by the power converter described herein. The transmission can contain a gearing for reducing the rotational rate of the electric machine and a differential.

The invention also relates to a vehicle that has an electric axle drive and/or a power converter. The vehicle is distinguished by the electric axle drive and/or the power converter described herein.

A method for producing one of the above variations of a cooling device is also proposed, comprising a step in which the heat sink with the heat discharging structure and the connecting surface, the semiconductor with the heat discharging surface, and the insulating layer containing a polymer with ceramic particles, are provided. The method also comprises a step in which the insulating layer is applied to the connecting surface on the heat sink and/or the discharge surface on the semiconductor, and a step for joining the heat sink, the semiconductor, and the insulating layer, in which the insulating layer is in between the connecting surface on the heat sink and the discharge surface on the semiconductor, in order to mechanically and thermally connect the heat sink to the semiconductor, and to electrically insulate them from one another.

The method can be automated. The advantages of the approach presented herein can also be obtained quickly and efficiently with this embodiment.

In one embodiment, the insulating layer can be applied to the heat sink and/or the semiconductor in one of numerous different curing stages in the application step, in particular in which a first curing stage can be a wet stage, a second curing stage can be a drying stage, and a third curing stage can be a dry stage. The curing stages can differ with regard to their degrees of wetness. By way of example, the wet stage can be wetter than the drying stage. The drying stage can then be wetter than the dry stage, but dryer than the wet stage. The curing stages can advantageously be defined by two different limit values relating to these wetness values, depending on the materials that are selected. This embodiment has the advantage that a particularly robust and reliable, as well as durable, connection can be obtained between the insulating layer, the heat sink, and the heat discharging structure through the determination of the curing stages.

In one embodiment, the insulating layer can be applied in the application step to the heat sink and/or the semiconductor through the application of pressure and heat. By way of example, the application pressure can be greater than a predefined pressure threshold, and the application heat can be higher than a threshold temperature, such that the material bonding of the semiconductor and the heat sink through the insulating layer can be advantageously ensured.

The approach presented herein also results in an apparatus that is designed to carry out, control or implement the steps in a variation of the method presented herein in corresponding devices. An object of the invention can also be quickly and efficiently achieved through this variant of an embodiment of the invention in the form of an apparatus.

An apparatus can be an electric device that processes electric signals, e.g. sensor signals, and outputs control signals on the basis thereof. The apparatus can contain one or more hardware or software interfaces. Hardware interfaces can be part of an integrated circuit in which functions of the apparatus are implemented. The interfaces can also be separate integrated circuits, or composed at least in part of discrete components. Software interfaces can be software modules on a microcontroller containing other software modules.

A computer program containing programming code that can be stored on a machine-readable medium such as a solid state disk, a hard disk, or an optical storage medium and is used to execute the method according to any of the embodiments described above in appropriated configured units when the program is executed on a computer or an apparatus is also advantageous.

The invention shall be explained in greater detail in reference to the drawings.

### BRIEF DESCRIPTION OF THE DRAWINGS

FIG. 1 shows a schematic illustration of a vehicle according to an exemplary embodiment;

FIG. 2 shows a schematic illustration of a cooling device for a power converter according to an exemplary embodiment;

FIG. 3 shows a schematic illustration of an exemplary embodiment of a cooling device for a power converter;

FIG. 4 shows a flow chart for an exemplary embodiment of a method for producing a cooling device; and

FIG. 5 shows a circuit diagram for an apparatus according to an exemplary embodiment.

### DETAILED DESCRIPTION

The same or similar reference symbols are used for all of the elements with similar functions shown in the drawings in the following description of preferred exemplary embodiments of the present invention, wherein there shall be no repetition of the explanations of these elements.

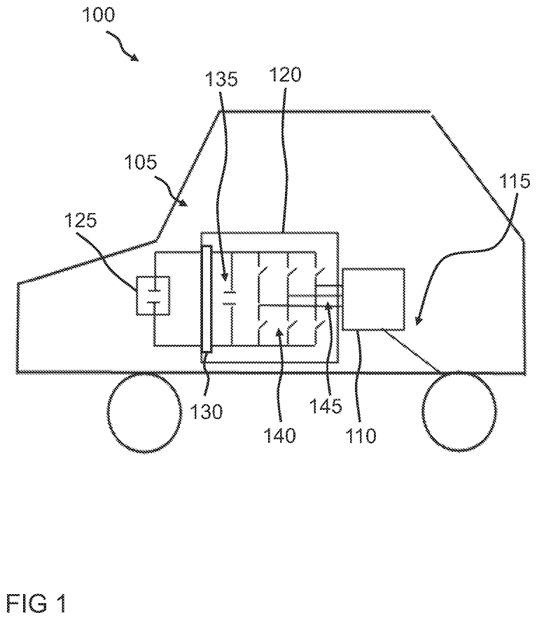

FIG. 1 shows a schematic illustration of a vehicle 100 according to an exemplary embodiment. The vehicle 100 can be a motor vehicle and contains an electric axle drive 105, which in turn contains at least one electric machine 110, an optional transmission 115, and a power converter 120. The power converter 120 is an inverter in this case, designed to convert direct current into alternating current. The electric machine 110 can be a drive unit or an electric motor, coupled to the optional transmission 115. The vehicle 100 also has a power supply unit 125 in the form of a rechargeable battery. The power supply unit 125 supplies electricity to vehicle components such as sensors and/or the electric machine 110. The power converter 120 in this exemplary embodiment is interconnected between the power supply unit 125 and the electric machine 110. The power converter 120 also has a cooling device 130 such as that describe in greater detail in reference to at least one of the following drawings, a capacitor 135, and numerous switches 140, e.g. six, which are coupled by numerous electrical lines 145 to the electric machine 110.

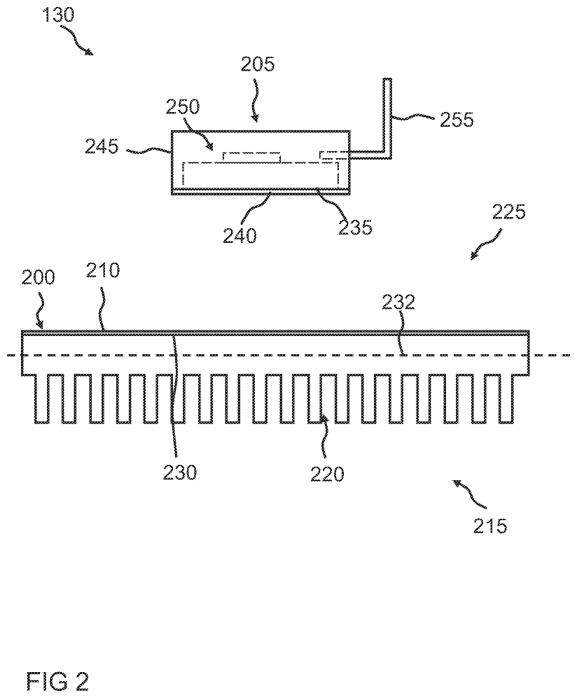

FIG. 2 shows a schematic illustration of a cooling device 130 for a power converter according to an exemplary embodiment. The cooling device 130 can be used for a power converter such as that described in reference to FIG. 1 as part of a vehicle. The cooling device 130 contains a heat sink 200, a semiconductor 205, and an insulating layer 210. By way of example, the semiconductor 205 can be a semiconductor switch 140 such as that described in reference to FIG. 1, e.g. a MOSFET switch, IGBT, or thyristor. The heat sink 200 has a heat discharging structure 220 on a first side 215 for discharging heat acting on the heat sink 200, and a connecting surface on a second side 225 for absorbing heat from the semiconductor 205 connected to the connecting surface 230. The heat discharging structure 220 is formed by fins at a right angle to the main axis of extension 232. The heat comes from the electricity to the semiconductor 205 or other electrical components in the power converter, and is removed by the heat sink 200 in order to prevent disruptions caused by overheating. The heat sink 200 contains a metal in this exemplary embodiment, e.g. copper or aluminum. The metal is selected on the basis of the properties of the material. Metals are normally good heat conductors, with which the heat from the semiconductor 205 can be removed efficiently. The semiconductor 205 also has a discharge surface 235 for discharging heat to the connecting surface 230 once the cooling device 130 is assembled and running, connected to the heat sink 200. The insulating layer 210 contains a polymer with ceramic particles embedded therein or applied thereto, and is in between the connecting surface 230 and the discharge surface 235. The insulating layer 210, or another insulating layer 240, can also be placed on the semiconductor 205, specifically on the discharge surface 235, in order to mechanically and thermally connect the heat sink 200 to the semiconductor 205 in a material bonded manner, and to electrically insulate them from one another. This means that the heat sink 200 and semiconductor 205 are glued together by the insulating layer 210 and/or the second insulating layer 240, thus eliminating the need for a soldering or sintering of the two components.

The semiconductor 205 is an uninsulated potted electronic component that is or can be connected to the heat sink 200. In this exemplary embodiment, the semiconductor 205 has a body 245 made of potting material that encases the electronic elements 250. The semiconductor also has an electrical lead wire 255 in this exemplary embodiment.

In other words, the insulating layer 210 is formed by a polymer/ceramic coating or film that forms both the insulation and the mechanical bond. The semiconductor 205 is a discrete semiconductor component, placed in a housing for the power converter, for example, and normally is not insulated. The thermal bonding and electrical insulation is therefore obtained with the insulating layer 210. This approach results in a simple system integration.

The insulating layer 210 can replace the previously typical ceramic insulation or insulating film. It also forms the material bond to the semiconductor 205. The insulating layer 210 applied in advance simplifies the assembly process for the power converter. The insulating layer 210 is applied to either the uninsulated, potted or molded semiconductor 210 or the heat sink 200. As explained above, the insulating layer 210 contains a polymer with ceramic particles. This insulating layer 210 is applied in different stages of the curing process, referred to as curing stages. A first curing stage is referred to as the A-state, and has the property, “not cured.” A second curing stage, the B-state, has the property, “partially cured.” The third curing stage, C-state, has the property, “fully cured.”

In this embodiment, the insulating layer 210 forms a thermal and mechanical bond that is also electrically insulating. Discrete semiconductors 205 without insulation are therefore potted and applied to the heat sink 200 using pressure and heat.

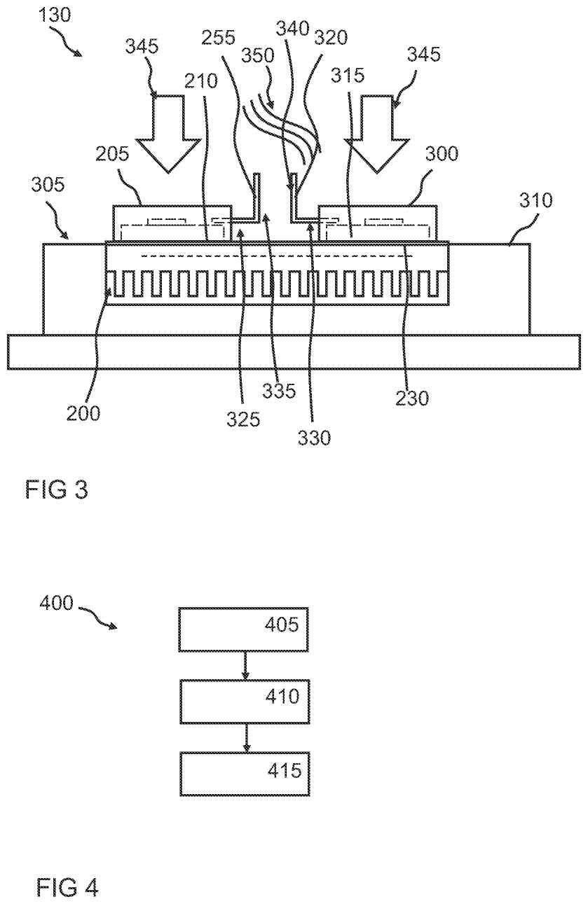

FIG. 3 shows a schematic illustration of an exemplary embodiment of a cooling device 130 for a power converter. The cooling device 130 is similar to the cooling device 130 described in reference to FIG. 2, and therefore also be used in a vehicle such as that described in reference to FIG. 1. In this exemplary embodiment, the cooling device 130 is ready for use, i.e. it is shown in the assembled state, such that the insulating layer 210 is between the semiconductor 200 and a second semiconductor 300. The cooling device is thermally and/or mechanically connected to the housing 305 for the power converter in this exemplary embodiment, such that the connecting surface 230 is flush within a tolerance range to an outer wall 310 of the housing 305. The tolerance range relates in particular to a range of play between the heat sink 200 and the outer wall 310 in order to compensate for any thermal expansion.

The cooling device 130 contains the second semiconductor 310 in this exemplary embodiment, which is analogous to the first semiconductor 205. The second semiconductor 310 also has a second discharge surface 315 with which the second semiconductor 310 is connected to the connecting surface 230. The insulating layer 210 in this exemplary embodiment is on the heat sink 200. A second insulating layer can also be placed on the second discharge surface 315, which is also formed by a polymer containing ceramic particles. The first insulating layer 210 and/or second insulating layer are also placed between the connecting surface 230 and the second discharge surface 315 on the second semiconductor 300 in this exemplary embodiment, and mechanically and thermally connect the heat sink 200 to the second semiconductor 300, while electrically insulating them from one another. As in FIG. 2, the semiconductor 205 in this exemplary embodiment also has an electrical lead wire 255. The second semiconductor 300 in this exemplary embodiment also has a second electric lead wire 320. The lead wires 255, 320 each have a coupling segment 325, 330 in this exemplary embodiment, which adjoins a connecting segment 335, 340. The first coupling segment 325 is at a right angle to the first connecting segment 335 and the second coupling segment 330 is at a right angle to the second connecting segment 340 in this exemplary embodiment, such that the first connecting segment 335 and second connecting segment 340 are parallel to one another. These lead wires 255, 320 can also have a different layout or configuration, depending on the application.

An application pressure 345 and application heat 350 also act on the cooling device 130 and thus the insulating layer 210 in this exemplary embodiment.

FIG. 4 shows a flow chart for an exemplary embodiment of a method 400 for producing a cooling device. The cooling device described in reference to FIGS. 1 to 3 is produced with this method 400. The method 400 can also be executed by a machine. The method 400 comprises a provision step 405, an application step 410, and a joining step 415. In the provision step 405, the heat sink with the heat discharging structure and the connecting surface, the semiconductor with the discharge surface, and the insulating layer containing a polymer with ceramic particles are provided. In the application step 410, the insulating layer is applied to the connecting surface of the heat sink and/or the discharge surface of the semiconductor. In the joining step 415, the heat sink, semiconductor, and insulating layer are joined such that the insulating layer is in between the connecting surface on the heat sink and the discharge surface on the semiconductor, and the heat sink and semiconductor are thermally and mechanically connected to one another and electrically insulated from one another. The insulating layer can optionally be applied to the heat sink and/or the semiconductor in one of numerous different curing stages in the application step 410. A first curing stage is referred to as a wet stage, a second curing stage forms a drying stage, and a third curing stage forms a dry stage. This means that the different curing stages differ in terms of their wetness. By way of example, these curing stages differ due to the material used for the insulating layer and/or with regard to the degrees of wetness in relation to one another. In this exemplary embodiment, this means that the wet stage is wetter than the drying stage and the dry stage. The drying stage is therefore in the middle, and is less wet than the wet stage and wetter than the dry stage. This also means that the dry stage is the driest of the three curing stages.

The insulating layer can optionally be applied in the application step 410 using an application pressure and application heat applied to the heat sink and/or the semiconductor. The application pressure is greater than a pressure threshold value and the application heat is higher than a temperature threshold value in this case.

In other words, an integration process for discrete components on a heat sink, also referred to as a “cooling plate,” is obtained in this exemplary embodiment for power converters that can be scaled, which are also referred to as inverters.

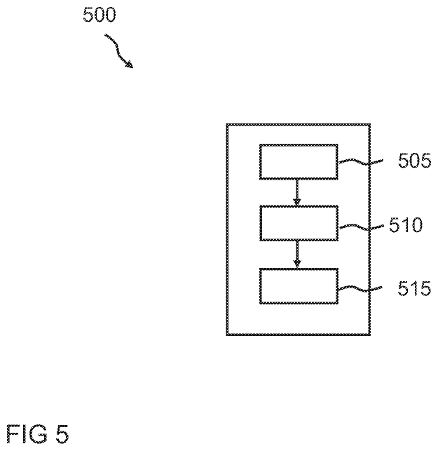

FIG. 5 shows a circuit diagram for an apparatus 500 according to an exemplary embodiment. The apparatus 500 forms a control unit that is configured for controlling and/or executing a method for producing a cooling device such as that described in reference to FIG. 4. The apparatus 500 has a provision unit 505, an application unit 510, and a joining unit 515, by way of example. The provision unit 505 is designed to provide the heat sink that has the heat discharging structure and the connecting surface, the semiconductor that has the discharge surface, and the insulating layer that has a polymer containing ceramic particles. The application unit 510 is designed to apply the insulating layer to the connecting surface on the heat sink and/or the discharge surface on the semiconductor. The joining unit 515 is designed to join the heat sink, the semiconductor, and the insulating layer such that the insulating layer is in between the connecting surface on the heat sink and the discharge surface on the semiconductor, in order to mechanically and thermally connect the heat sink to the semiconductor, and to electrically insulate them from one another.

The exemplary embodiments described in reference to the drawings are selected merely by way of example. Different exemplary embodiments can be combined with one another, in their entirety or with regard to individual features. One exemplary embodiment can also be supplemented by features of another exemplary embodiment.

The steps in the method can also be repeated or carried out in a different order than that described herein.

If an exemplary embodiment contains an “and/or” conjunction between a first feature and a second feature, this can be read to mean that the exemplary embodiment in one version contains both the first and second features, and in another version, contains either just the first feature or just the second feature.

### LIST OF REFERENCE SYMBOLS

100 vehicle
105 electric axle drive
110 electric machine
115 transmission
120 power converter
125 power supply unit
130 cooling device
135 capacitor
140 switches
145 electric lead wires
200 heat sink
205 semiconductor
210 insulating layer
215 first side
220 heat discharging structure
225 second side
230 connecting surface
232 main axis of extension
235 discharge surface
240 second insulating layer
245 corpus
250 electronic elements
255 connecting wire
300 second semiconductor
305 housing
310 outer wall
315 second discharge surface
320 second connecting wire
325 first coupling segment
330 second coupling segment
335 first connecting segment
340 second connecting segment
345 application pressure
350 application heat
400 method for producing a cooling device
405 provision step
410 application step
415 joining step
500 apparatus
505 provision unit
510 application unit
515 joining unit

1. A cooling device for a power converter for a vehicle, comprising:
a heat sink comprising a heat discharging structure on a first side for discharging heat acting on the heat sink, and a connecting surface on a second side opposite the first side for absorbing heat from a semiconductor connected to the connecting surface;
the semiconductor comprising a discharge surface for discharging heat to the connecting surface; and
an insulating layer comprising a polymer with ceramic particles located between the connecting surface on the heat sink and the discharge surface on the semiconductor, wherein the insulating layer is designed to mechanically and thermally connect the heat sink to the semiconductor and to insulate them from one another.

2. The cooling device according to claim 1, wherein the insulating layer is materially bonded to the connecting surface and the discharge surface.

3. The cooling device according to claim 1, wherein the insulating layer has ceramic particles embedded in or applied to the polymer.

4. The cooling device according to claim 1, wherein the semiconductor is a potted electronic component.

5. The cooling device according to claim 1, comprising:
at least one further semiconductor that has a second discharge surface for placing the second semiconductor on the connecting surface,
wherein the insulating layer and/or a second insulating layer, which also has a polymer with ceramic particles, is placed between the connecting surface and the second discharge surface on the second semiconductor to mechanically and thermally connect the heat sink and the second semiconductor and electrically insulate them from one another.

6. The cooling device according to claim 1, wherein the heat sink comprises a metal.

7. The cooling device according to claim 6, wherein the metal comprises copper or aluminum.

8. A power converter comprising the cooling device according to claim 1.

9. The power converter according to claim 8, wherein the power converter comprises an inverter.

10. The power converter according to claim 8, comprising:
a housing,
wherein the cooling device is thermally and/or mechanically coupled to the housing.

11. The power converter according to claim 8, comprising:
a housing,
wherein the connecting surface of the heat sink is flush with an outer wall of the housing.

12. An electric axle drive for a motor vehicle, comprising:
at least one electric machine;
a transmission; and
a power converter according to claim 8.

13. A vehicle, comprising:
the cooling device according to claim 1.

14. A method for producing a cooling device, the method comprising:
providing a heat sink having a heat discharging structure and a connecting surface;
providing a semiconductor having a discharge surface; and
providing an insulating layer having a polymer with ceramic particles;
applying the insulating layer to the connecting surface on the heat sink and/or to the discharge surface on the semiconductor; and
joining the heat sink, the semiconductor, and the insulating layer,
wherein the insulating layer is between the connecting surface on the heat sink and the discharge surface on the semiconductor to mechanically and thermally connect the heat sink to the semiconductor and to electrically insulate them from one another.

15. The method according to claim 14, comprising:
applying the insulating layer to the heat sink and/or to the semiconductor in one of a plurality of different curing stages, wherein a first curing stage is a wet stage, a second curing stage is a drying stage, and a third curing stage is a dry stage.

16. The method according to claim 14, comprising:
applying the insulating layer to the heat sink and/or the semiconductor using an application pressure and an application heat.

17. An apparatus comprising:
at least one computing device that is configured to cause the apparatus to execute the method according to claim 14.

18. A non-transitory computer-readable medium having stored therein a computer program that, when executed by a computer, causes the computer to control at least one apparatus to execute the method according to claim 14.
